(19) United States
(12) Patent Application Publication
(10) Pub. No.: US 2026/0148770 A1
(43) Pub. Date: May 28, 2026

(54) NON-VOLATILE MEMORY DEVICE ENABLING MEMORY PLANE CIRCUIT, STORAGE DEVICE INCLUDING THE SAME, AND METHOD OF OPERATING THE SAME

(71) Applicant: Samsung Electronics Co., Ltd., Suwon-si (KR)

(72) Inventors: Jungmin Park, Suwon-si (KR); Hyunkook Park, Suwon-si (KR); Ji-Sang Lee, Suwon-si (KR)

(21) Appl. No.: 19/325,200

(22) Filed: Sep. 10, 2025

(30) Foreign Application Priority Data
Nov. 28, 2024 (KR) 10-2024-0173932

(51) Int. Cl. G11C 16/24; G11C 16/10; G11C 16/26; G11C 16/30

(52) U.S. Cl. CPC G11C 16/24; G11C 16/102; G11C 16/26; G11C 16/30

(57) ABSTRACT

A non-volatile memory device that includes a first page buffer circuit, a first sub-memory plane circuit directly connected to the first page buffer circuit through first bit lines, a second sub-memory plane circuit directly connected to the first page buffer circuit through second bit lines different from the first bit lines, and a control logic circuit. The control logic circuit receives a command from a storage controller, determines whether the command indicates first type information or second type information, enables the first sub-memory plane circuit and the second sub-memory plane circuit in response to determining that the command indicates the first type information, and enables the first sub-memory plane circuit in response to determining that the command indicates the second type information.

### CROSS-REFERENCE TO RELATED APPLICATIONS

This application claims priority under 35 U.S.C. § 119 to Korean Patent Application No. 10-2024-0173932, filed on Nov. 28, 2024, in the Korean Intellectual Property Office, the disclosures of which are incorporated by reference herein in their entireties.

### BACKGROUND

A memory device stores data in response to a write request and outputs data stored therein in response to a read request. For example, the memory device is classified as a volatile memory device, which loses data stored therein when a power is turned off, such as a dynamic random access memory (DRAM) device or a static RAM (SRAM) device, or a non-volatile memory device, which retains data stored therein even when a power is turned off, such as a flash memory device, a phase-change RAM (PRAM), a magnetic RAM (MRAM), or a resistive RAM (RRAM).

The non-volatile memory device may include a plurality of memory plane circuits. The non-volatile memory device may perform a memory operation in each of the plurality of memory plane circuits, such as a read operation, a program operation, or an erase operation. The non-volatile memory device may perform the memory operations in the plurality of memory plane circuits in parallel. As the number of memory plane circuits controlled in parallel increases, an operation speed of the non-volatile memory device may increase, but a chip size of the non-volatile memory device may increase.

### SUMMARY

In general, the present disclosure is directed toward a non-volatile memory device enabling a memory plane circuit, a storage device including the same, and a method of operating the same.

According to some implementations, the present disclosure is directed to a non-volatile memory device that includes a first page buffer circuit, a first sub-memory plane circuit directly connected to the first page buffer circuit through first bit lines, a second sub-memory plane circuit directly connected to the first page buffer circuit through second bit lines different from the first bit lines, and a control logic circuit. The control logic circuit receives a command from a storage controller, determines whether the command indicates first type information or second type information, enables the first sub-memory plane circuit and the second sub-memory plane circuit in response to determining that the command indicates the first type information, and enables the first sub-memory plane circuit in response to determining that the command indicates the second type information.

According to some implementations, the present disclosure is directed to a storage device that includes a storage controller that generates a command, and a non-volatile memory device that includes a first page buffer circuit, a first sub-memory plane circuit, and a second sub-memory plane circuit. The first page buffer circuit is directly connected to the first sub-memory plane circuit and the second sub-memory plane circuit. The non-volatile memory device receives the command from the storage controller, determines whether the command indicates first type information or second type information, enables the first sub-memory plane circuit and the second sub-memory plane circuit in response to determining that the command indicates the first type information, and enables the first sub-memory plane circuit in response to determining that the command indicates the second type information.

According to some implementations, the present disclosure is directed to a method of operating a non-volatile memory device that communicates with a storage controller and includes receiving a command from the storage controller, determining whether the command indicates first type information or second type information, enabling a first sub-memory plane circuit and a second sub-memory plane circuit of the non-volatile memory device in response to determining that the command indicates the first type information, the first sub-memory plane circuit and the second sub-memory plane circuit being directly connected to a first page buffer circuit of the non-volatile memory device, and enabling the first sub-memory plane circuit in response to determining that the command indicates the second type information.

### BRIEF DESCRIPTION OF THE DRAWINGS

Example implementation will be more clearly understood from the following detailed explanation, taken in conjunction with the accompanying drawings.

FIG. 1 is a block diagram of an example of an electronic device according to some implementations.

FIG. 2 is a block diagram describing an example of anon-volatile memory device.

FIG. 3 is a diagram showing a plane region of a non-volatile memory device of FIG. 2.

FIG. 4 is a block diagram showing an example of a non-volatile memory device according to some implementations.

FIG. 5 is a diagram showing an example of a plane region of FIG. 4 according to some implementations.

FIG. 6 is a table showing an example of a page buffer circuit and a command according to some implementations.

FIG. 7 is a table showing an example of an operating speed of a non-volatile memory device according to some implementations.

FIG. 8 is a diagram showing an example of a method of operating a non-volatile memory device according to some implementations.

FIG. 9 is a diagram showing an example of a first-type multi-plane operation according to some implementations.

FIG. 10 is a diagram showing an example of a second-type multi-plane operation according to some implementations.

FIG. 11 is a flowchart showing an example of a method of operating a non-volatile memory device according to some implementations.

FIG. 12 is a flowchart showing an example of a method of operating a non-volatile memory device according to some implementations.

### DETAILED DESCRIPTION

Hereinafter, example implementations will be explained in detail with reference to the accompanying drawings.

As used herein, each of the phrases such as “A or B”, “at least one of A or B”, “at least one of A or B”, “at least one of A, B, or C”, “at least one of A, B, and C”, and “at least one of B or C”, including the claims, may include any one of items listed together in the corresponding phrase, or all possible combinations thereof.

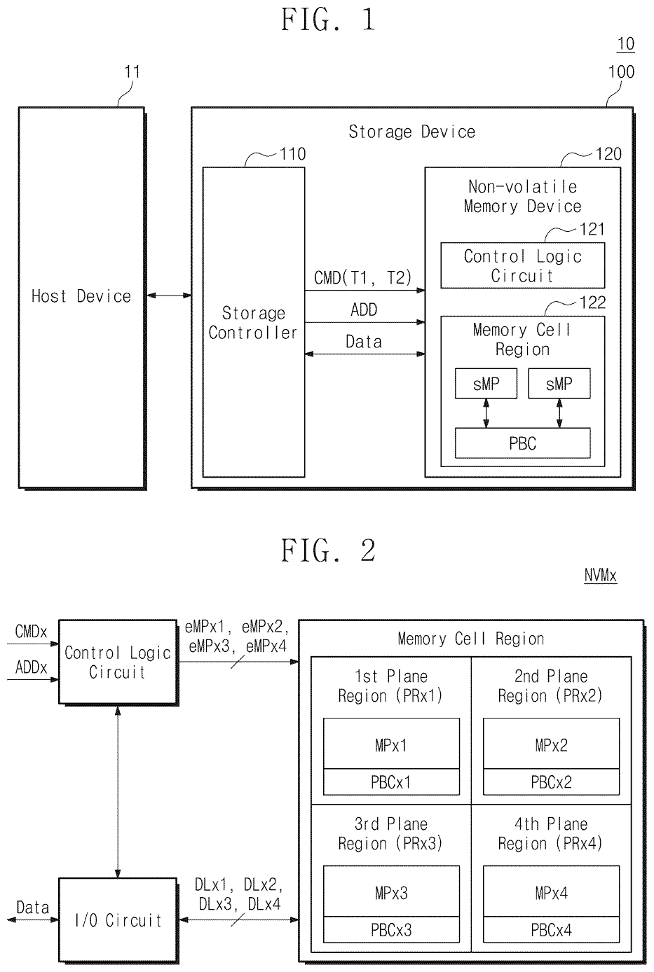

FIG. 1 is a block diagram showing an example of an electronic device according to some implementations. In FIG. 1, an electronic device 10 may include a host device 11 and a storage device 100. The electronic device 10 may include an electronic system configured to process a variety of information or to store the processed information as data. For example, the electronic device 10 may be implemented with a storage system, a server system, a database server, etc. for managing a large amount of user data. In some implementations, the electronic device 10 may be implemented with a computing system, which is configured to process a variety of information, such as a personal computer (PC), a notebook, a laptop, a server, a workstation, a tablet PC, a smartphone, a digital camera, and a black box.

The host device 11 may control all operations of the electronic device 10. The host device 11 may store data in the storage device 100, may read data stored in the storage device 100, or may delete data stored in the storage device 100. For example, the host device 11 may include a processor such as a central processing unit (CPU), a graphics processing unit (GPU), a neural processing unit (NPU), or a digital signal processor unit (DSP).

The storage device 100 may include a storage controller 110 and a non-volatile memory device 120. The storage controller 110 may store data in the non-volatile memory device 120 under control of the host device 11. The storage controller 110 may generate a command CMD and an address ADD. The storage controller 110 may receive data from the host device 11 or the non-volatile memory device 120.

In detail, the storage controller 110 may provide the non-volatile memory device 120 with the command CMD indicating the memory operation such as a read operation, a program operation, or an erase operation. The storage controller 110 may provide the non-volatile memory device 120 with the address ADD indicating a location where the memory operation will be performed. The storage controller 110 may provide data received from the host device 11 to the non-volatile memory device 120 or may provide data received from the non-volatile memory device 120 to the host device 11.

In some implementations, the command CMD may indicate first type information T1 or second type information T2. The type information may be used to determine a sub-memory plane circuit to be enabled from among sub-memory plane circuits sMP of the non-volatile memory device 120. For example, the first type information T1 may indicate the enable of all the sub-memory plane circuits sMP. The second type information T2 may indicate the enable of some of the sub-memory plane circuits sMP.

The non-volatile memory device 120 may include a control logic circuit 121 and a memory cell region 122. The non-volatile memory device 120 may store data under control of the storage controller 110. The non-volatile memory device 120 may retain data present therein even though a power is turned off. For example, the non-volatile memory device 120 may be implemented with a NAND flash memory device, a NOR flash memory device, a phase-change RAM (PRAM), a magnetic RAM (MRAM), a resistive RAM (RRAM), etc.

The control logic circuit 121 may receive the command CMD and the address ADD from the storage controller 110. The control logic circuit 121 may control all operations of the non-volatile memory device 120 based on the command CMD and the address ADD. For example, the control logic circuit 121 may store data in the memory cell region 122, may read data stored in the memory cell region 122, or may delete data stored in the memory cell region 122.

The memory cell region 122 may include the plurality of sub-memory plane circuits sMP and a page buffer circuit PBC. The sub-memory plane circuits sMP may include a plurality of memory cell transistors for storing data. The page buffer circuit PBC may sense voltage levels corresponding to data stored or to be stored in the sub-memory plane circuit sMP and may temporarily store the sensed voltage levels.

The plurality of sub-memory plane circuits sMP may share the page buffer circuit PBC. For example, the plurality of sub-memory plane circuits sMP may be directly connected to the page buffer circuit PBC through corresponding bit lines. The bit line may be connected in series to some of the memory cell transistors of the sub-memory plane circuit sMP. The page buffer circuit PBC may include a plurality of latch circuits. At least some of the plurality of latch circuits may temporarily store data corresponding to different sub-memory plane circuits sMP.

In some implementations, the control logic circuit 121 may enable the sub-memory plane circuit sMP based on the type information. For example, the control logic circuit 121 may determine whether the command CMD indicates the first type information T1 or the second type information T2. The control logic circuit 121 may enable all the sub-memory plane circuits sMP in response to determining that the command CMD indicates the first type information T1. The control logic circuit 121 may enable some of all the sub-memory plane circuits sMP in response to determining that the command CMD indicates the second type information T2.

In some implementations, the sub-memory plane circuit sMP may support a low level cell manner and a high level cell manner. For example, the sub-memory plane circuit sMP of the non-volatile memory device 120 may store data in the low level cell manner of an N-bit size or may store data in the high level cell manner of an M-bit size. “N” is an arbitrary natural number. “M” is a natural number greater than “N”.

In this case, the high level cell manner and the low level cell manner may be determined relatively depending on maximum performance supported by the non-volatile memory device 120. For example, a memory cell transistor may be implemented in a single level cell (SLC) manner for storing one bit, a multi-level cell (MLC) manner for storing two bits, a triple level cell (TLC) manner for storing three bits, a quadruple level cell (QLC) manner for storing four bits, etc. In the non-volatile memory device 120 supporting the SLC manner to the MLC manner, the MLC manner may be referred to as a “high level cell manner”; in the non-volatile memory device 120 supporting the SLC manner to the QLC manner, the MLC manner may be referred to as a “low level cell manner”.

In some implementations, the type information may be differently implemented depending on whether a cell manner is the low level cell manner or the high level cell manner. For example, the first type information T1 may correspond to a first read operation for obtaining data stored in the low level cell manner of the N-bit size, a first program operation for storing data in the low level cell manner of the N-bit size, a second read operation for obtaining data stored in the high level cell manner of the M-bit size, and an erase operation for deleting data stored regardless of a manner. The second type information T2 may correspond to a second program operation for storing data in the high level cell manner of the M-bit size.

In the present disclosure, the examples of the first type information T1 and the second type information T2 are described, but the present disclosure is not limited thereto. Examples of the first type information T1 and the second type information T2 may be implemented differently from the above examples. In some implementations, the command CMD may be classified into three or more type information, and the control logic circuit 121 may enable all, majority, or minority of the sub-memory plane circuits sMP based on three or more type information.

FIG. 2 is a block diagram showing a non-volatile memory device. In FIG. 2, a non-volatile memory device NVMx may include a control logic circuit, a memory cell region, and an input/output (I/O) circuit. For better understanding of the present disclosure, the non-volatile memory device NVMx will be described. The non-volatile memory device NVMx is not intended to limit the scope of the present disclosure.

The memory cell region may include first to fourth plane regions PRx1 to PRx4. The plane region may refer to a physical space in which a page buffer circuit and at least one memory plane circuit are disposed. The first plane region PRx1 may include a first memory plane circuit MPx1 and a first page buffer circuit PBCx1. The first memory plane circuit MPx1 may include a plurality of memory cell transistors. The plurality of memory cell transistors of the first memory plane circuit MPx1 may be directly connected to the first page buffer circuit PBCx1 through corresponding bit lines. The first page buffer circuit PBCx1 may operate under control of the control logic circuit. The first page buffer circuit PBCx1 may be dedicated to the first memory plane circuit MPx1. In the present disclosure, the expression ‘be dedicated to’ may refer to ‘exclusively used’ or ‘not shared’. For example, the page buffer circuit PBCx1 may temporarily store data of the first memory plane circuit MPx1, while the page buffer circuit PBCx1 may not store data of the second memory plane circuit MPx2, the third memory plane circuit MPx3, and/or the fourth memory plane circuit MPx4.

As in the above description, the second plane region PRx2 may include a second memory plane circuit MPx2 and a second page buffer circuit PBCx2. The third plane region PRx3 may include a third memory plane circuit MPx3 and a third page buffer circuit PBCx3. The fourth plane region PRx4 may include a fourth memory plane circuit MPx4 and a fourth page buffer circuit PBCx4.

The control logic circuit may receive a command CMDx and an address ADDx from a storage controller. The control logic circuit may generate enable signals eMPx1 to eMPx4 based on the command CMDx and the address ADDx. The enable signals eMPx1 to eMPx4 may be used to enable the first to fourth memory plane circuits MPx1 to MPx4, respectively. The control logic circuit may perform the memory operations in parallel in the first to fourth memory plane circuits MPx1 to MPx4 based on the enable signals eMPx1 to eMPx4.

Under control of the control logic circuit, the I/O circuit may store data received from the storage controller in the memory cell region or may provide data stored in the memory cell region to the storage controller (not illustrated). The I/O circuit may be directly connected to the memory cell region through first to fourth data lines DLx1 to DLx4.

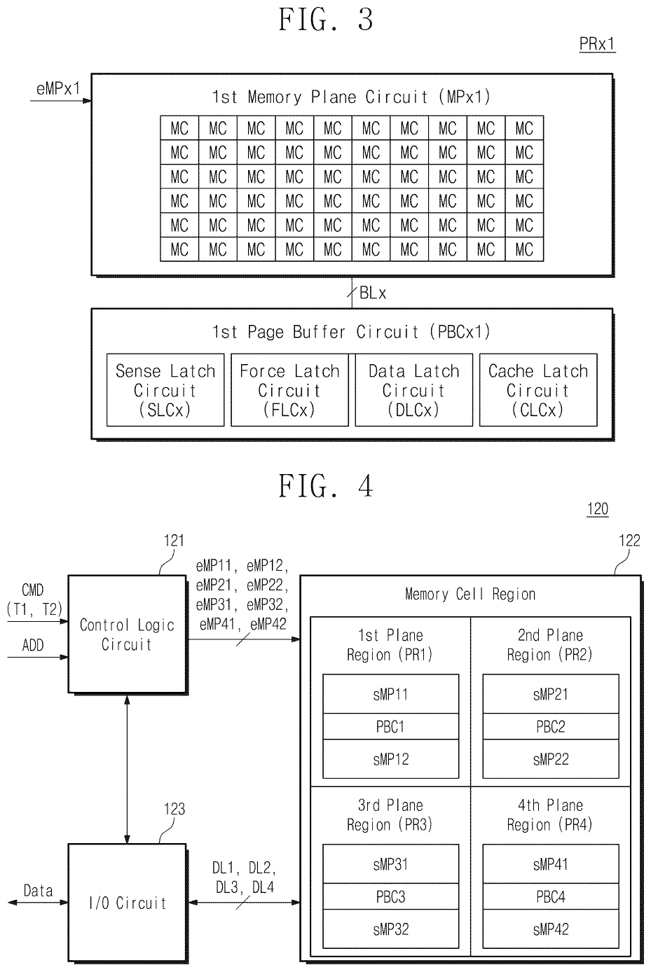

FIG. 3 is a diagram showing a plane region of a non-volatile memory device of FIG. 2. In FIGS. 2 and 3, the non-volatile memory device NVMx may include the first plane region PRx1. In the present disclosure, the plane region of the non-volatile memory device NVMx will be described. The plane region is not intended to limit the scope of the present disclosure.

The first plane region PRx1 may include the first memory plane circuit MPx1 and the first page buffer circuit PBCx1. The first memory plane circuit MPx1 may receive the enable signal eMPx1 from the control logic circuit. The first memory plane circuit MPx1 may be enabled based on the enable signal eMPx1.

The first memory plane circuit MPx1 may include a plurality of memory cell transistors MC. The plurality of memory cell transistors MC may be connected in series to the first page buffer circuit PBCx1 through bit lines BLx. Each of the plurality of memory cell transistors MC may be connected to the corresponding bit line BLx and may be controlled in response to a voltage applied by the control logic circuit through a corresponding word line (not illustrated).

The first page buffer circuit PBCx1 may include a sense latch circuit SLCx, a force latch circuit FLCx, a data latch circuit DLCx, and a cache latch circuit CLCx. The sense latch circuit SLCx, the force latch circuit FLCx, the data latch circuit DLCx, and the cache latch circuit CLCx may be dedicated to the first memory plane circuit MPx1.

The sense latch circuit SLCx may sense voltage levels corresponding to the memory cell transistors MC of the first memory plane circuit MPx1.

The force latch circuit SLCx may adjust a distribution of the voltage levels corresponding to the memory cell transistors MC of the first memory plane circuit MPx1.

The data latch circuit SLCx may perform a data latch operation of data to be programmed in the memory cell transistors MC of the first memory plane circuit MPx1. The data latch operation may refer to an operation of temporarily storing the data to be programmed.

The cache latch circuit CLCx may perform a cache latch operation of data read from the memory cell transistors MC of the first memory plane circuit MPx1 or data to be programmed in the memory cell transistors MC of the first memory plane circuit MPx1. The cache latch operation may refer to an operation of temporarily storing the read data or the data to be programmed. The cache latch circuit CLCx may be connected to the I/O circuit through the first data line DL1x.

The components of the non-volatile memory device NVMx are described above. The operation speed of the non-volatile memory device NVMx may depend on the throughput of the memory plane circuit and the number of memory plane circuits.

The throughput may be increased by miniaturizing the memory plane circuit, but the miniaturization may be limited due to various factors such as a process error or operation stability. When the number of memory plane circuits operating in parallel increases, a chip size may be increased due to the increase of required plane regions. There may be required a technique for increasing the operation speed within the limited chip size.

FIG. 4 is a block diagram showing an example of a non-volatile memory device according to some implementations. In FIG. 4, a non-volatile memory device 120 may include the control logic circuit 121, a memory cell region 122, and an I/O circuit 123. The non-volatile memory device 120 may receive the command CMD and the address ADD from the storage controller 110 of FIG. 1. The non-volatile memory device 120 may communicate data with the storage controller 110 of FIG. 1.

The memory cell region 122 may include first to fourth plane regions PR1 to PR4. The areas of the first to fourth plane regions PR1 to PR4 may be similar to the areas of the first to fourth plane regions PRx1 to PRx4 of FIG. 2. The plane region may refer to a physical space in which a page buffer circuit and at least one memory plane circuit sharing the page buffer circuit are disposed.

The first plane region PR1 may include a first sub-memory plane circuit sMP11, a second sub-memory plane circuit sMP12, and a first page buffer circuit PBC1. Each of the first and second sub-memory plane circuits sMP11 and sMP12 may include a plurality of memory cell transistors. The plurality of memory cell transistors of the first sub-memory plane circuit sMP11 may be directly connected to the first page buffer circuit PBC1 through corresponding bit lines. The plurality of memory cell transistors of the second sub-memory plane circuit sMP12 may be directly connected to the first page buffer circuit PBC1 through corresponding other bit lines. The first page buffer circuit PBC1 may operate under control of the control logic circuit 121. Each of the first and second sub-memory plane circuits sMP11 and sMP12 may share the first page buffer circuit PBC1.

As in the above description, the second plane region PR2 may include a first sub-memory plane circuit sMP21, a second sub-memory plane circuit sMP22, and a second page buffer circuit PBC2. The third plane region PR3 may include a first sub-memory plane circuit sMP31, a second sub-memory plane circuit sMP32, and a third page buffer circuit PBC3. The fourth plane region PR4 may include a first sub-memory plane circuit sMP41, a second sub-memory plane circuit sMP42, and a fourth page buffer circuit PBC4.

The control logic circuit 121 may receive the command CMD and the address ADD from the storage controller 110 of FIG. 1. The command CMD may indicate the first type information T1 or the second type information T2. The first type information T1 may indicate the enable of all sub-memory plane circuits sharing a page buffer circuit. The second type information T2 may indicate the enable of some of all sub-memory plane circuits sharing a page buffer circuit. The address ADD may indicate a location where the memory operation corresponding to the command CMD will be performed.

The control logic circuit 121 may generate all or some of enable signals eMP11, eMP12, eMP21, eMP22, eMP31, eMP32, eMP41, and eMP42 respectively corresponding to the sub-memory plane circuits sMP11, sMP12, sMP21, sMP22, sMP31, sMP32, sMP41, and sMP42.

For example, the control logic circuit 121 may generate the enable signals eMP11, eMP12, eMP21, eMP22, eMP31, eMP32, eMP41, and eMP42 in response to determining that the command CMD indicates the first type information T1 and may perform the memory operations in parallel in all the sub-memory plane circuits sMP11, sMP12, sMP21, sMP22, sMP31, sMP32, sMP41, and sMP42 based on the enable signals eMP11, eMP12, eMP21, eMP22, eMP31, eMP32, eMP41, and eMP42.

As another example, the control logic circuit 121 may generate the enable signals eMP11, eMP21, eMP31, and eMP41 in response to determining that the command CMD indicates the second type information T2 and may perform the memory operations in parallel in some sub-memory plane circuits sMP11, sMP21, sMP31, and sMP41 among the sub-memory plane circuits sMP11, sMP12, sMP21, sMP22, sMP31, sMP32, sMP41, and sMP42 based on the enable signals eMP11, eMP21, eMP31, and eMP41.

In some implementations, the control logic circuit 121 may generate the enable signals eMP12, eMP22, eMP32, and eMP42 in response to determining that the command CMD indicates the second type information T2 and may perform the memory operations in parallel in other sub-memory plane circuits sMP12, sMP22, sMP32, and sMP42 among the sub-memory plane circuits sMP11, sMP12, sMP21, sMP22, sMP31, sMP32, sMP41, and sMP42 based on the enable signals eMP12, eMP22, eMP32, and eMP42.

Under control of the control logic circuit 121, the I/O circuit 123 may provide data received from the storage controller 110 of FIG. 1 to the memory cell region 122 or may provide data stored in the memory cell region 122 to the storage controller 110 of FIG. 1. The I/O circuit 123 may be directly connected to the memory cell region 122 through first to fourth data lines DL1 to DL4.

In detail, the first data line DL1 may be directly connected to the I/O circuit 123 and the first page buffer circuit PBC1. The first data line DL1 may transfer data corresponding to the program operation from the I/O circuit 123 to the first page buffer circuit PBC1. The first data line DL1 may transfer data corresponding to the read operation from the first page buffer circuit PBC1 to the I/O circuit 123.

As in the above description, the second data line DL2 may be directly connected to the I/O circuit 123 and the second page buffer circuit PBC2. The third data line DL3 may be directly connected to the I/O circuit 123 and the third page buffer circuit PBC3. The fourth data line DL4 may be directly connected to the I/O circuit 123 and the fourth page buffer circuit PBC4.

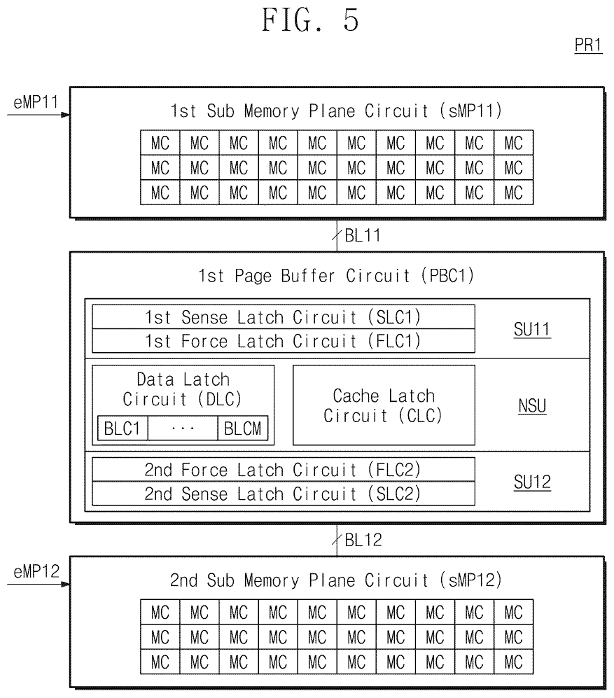

FIG. 5 is a diagram showing an example of a plane region of FIG. 4 according to some implementations. In FIGS. 4 and 5, the non-volatile memory device 120 may include the first plane region PR1. The first plane region PR1 may include the first sub-memory plane circuit sMP11, the second sub-memory plane circuit sMP12, and the first page buffer circuit PBC1.

The control logic circuit 121 may generate the enable signals eMP11 and eMP12 in response to that the command CMD indicates the first type information T1. The control logic circuit 121 may generate the enable signal eMP11 in response to that the command CMD indicates the second type information T2. In some implementations, the control logic circuit 121 may generate the enable signal eMP12 in response to that the command CMD indicates the second type information T2.

The first sub-memory plane circuit sMP11 may receive the enable signal eMP11 from the control logic circuit 121. The first sub-memory plane circuit sMP11 may be enabled based on the enable signal eMP11. The second sub-memory plane circuit sMP12 may receive the enable signal eMP12 from the control logic circuit 121. The second sub-memory plane circuit sMP12 may be enabled based on the enable signal eMP12.

The first sub-memory plane circuit sMP11 may include a plurality of memory cell transistors MC. The memory cell transistors MC of the first sub-memory plane circuit sMP11 may be directly connected to the first page buffer circuit PBC1 through first bit lines BL11. Each of the memory cell transistors MC of the first sub-memory plane circuit sMP11 may be connected to one of the first bit lines BL11 and may be controlled in response to a voltage applied by the control logic circuit 121 through a corresponding word line.

As in the above description, the second sub-memory plane circuit sMP12 may include a plurality of memory cell transistors MC. The memory cell transistors MC of the second sub-memory plane circuit sMP12 may be directly connected to the first page buffer circuit PBC1 through second bit lines BL12. Each of the memory cell transistors MC of the second sub-memory plane circuit sMP12 may be connected to one of the second bit lines BL12 and may be controlled in response to a voltage applied by the control logic circuit 121 through a corresponding word line (not illustrated).

The control logic circuit 121 may control the first page buffer circuit PBC1 based on the command CMD. The command CMD may indicate the memory operation. Examples of the memory operation may include the first read operation for obtaining data stored in the low level cell manner of the N-bit size, the first program operation for storing data in the low level cell manner of the N-bit size, the second read operation for obtaining data stored in the high level cell manner of the M-bit size, the second program operation for storing data in the high level cell manner of the M-bit size, and the erase operation for deleting data stored regardless of a manner. “N” is an arbitrary natural number. “M” is a natural number greater than “N”. In this case, the first read operation, the first program operation, the second read operation, and the erase operation may correspond to the first type information T1. The second program operation may correspond to the second type information T2.

The first page buffer circuit PBC1 may be shared by the first and second sub-memory plane circuits sMP11 and sMP12. The first page buffer circuit PBC1 may include a first sense unit SU11, a second sense unit SU12, and a non-sense unit NSU. The unit may refer to a set of latch circuits.

The first sense unit SU11 may include a first sense latch circuit SLC1 and a first force latch circuit FLC1. The first sense unit SU11 may be dedicated to the first sub-memory plane circuit sMP11.

Under control of the control logic circuit 121, the first sense latch circuit SLC1 may sense voltage levels corresponding to the memory cell transistors MC of the first sub-memory plane circuit sMP11, based on the first read operation, the first program operation, the second read operation, the second program operation, or the erase operation. The first sense latch circuit SLC1 may be dedicated to the first sub-memory plane circuit sMP11.

Under control of the control logic circuit 121, the first force latch circuit FLC1 may adjust a distribution of the voltage levels corresponding to the memory cell transistors MC of the first sub-memory plane circuit sMP11, based on the first read operation, the first program operation, the second read operation, or the second program operation. The first force latch circuit FLC1 may be dedicated to the first sub-memory plane circuit sMP11.

The second sense unit SU12 may include a second sense latch circuit SLC2 and a second force latch circuit FLC2. The second sense unit SU12 may be dedicated to the second sub-memory plane circuit sMP12.

Under control of the control logic circuit 121, the second sense latch circuit SLC2 may sense voltage levels corresponding to the memory cell transistors MC of the second sub-memory plane circuit sMP12, based on the first read operation, the first program operation, the second read operation, the second program operation, or the erase operation. The second sense latch circuit SLC2 may be dedicated to the second sub-memory plane circuit sMP12.

Under control of the control logic circuit 121, the second force latch circuit FLC2 may adjust a distribution of the voltage levels corresponding to the memory cell transistors MC of the second sub-memory plane circuit sMP12, based on the first read operation, the first program operation, the second read operation, or the second program operation. The second force latch circuit FLC2 may be dedicated to the second sub-memory plane circuit sMP12.

The non-sense unit NSU may include a data latch circuit DLC and a cache latch circuit CLC. The data latch circuit DLC may include first to M-th bit latch circuits BLC1 to BLCM. The non-sense unit NSU may be shared by the first and second sub-memory plane circuits sMP11 and sMP12.

Under control of the control logic circuit 121, the data latch circuit DLC may perform the data latch operation of data (i.e., data to be programmed) corresponding to the memory cell transistors MC of the first sub-memory plane circuit sMP11 or the second sub-memory plane circuit sMP12, based on the second program operation. The data latch operation may refer to an operation of temporarily storing the data to be programmed. The data latch circuit DLC may be shared by the first and second sub-memory plane circuits sMP11 and sMP12.

In some implementations, the data latch operation may include a plurality of bit latch operations. For example, data for the data latch operation may include first to M-th bits. The data latch operation may include first to M-th bit latch operations respectively corresponding to the first to M-th bits. Under control of the control logic circuit 121, the data latch circuit DLC may include the first to M-th bit latch circuits BLC1 to BLCM configured to perform the first to M-th bit latch operations, based on the second program operation.

Under control of the control logic circuit 121, the cache latch circuit CLC may perform the cache latch operation of data (e.g., read data or data to be programmed) corresponding to the memory cell transistors MC of the first sub-memory plane circuit sMP11 or the second sub-memory plane circuit sMP12, based on the first read operation, the first program operation, the second read operation, or the second program operation. The cache latch operation indicate may refer to an operation of temporarily storing the read data or the data to be programmed. The cache latch circuit CLC may be connected to the I/O circuit 123 through the first data line DL1. The cache latch circuit CLC may be shared by the first and second sub-memory plane circuits sMP11 and sMP12.

To avoid the duplication of description, the first plane region PR1 among the first to fourth plane regions PR1 to PR4 of the non-volatile memory device 120 is described, but the present disclosure is not limited thereto. The above description will be similarly applied to the second to fourth plane regions PR2 to PR4.

In some implementations, the first plane region PR1 may include three or more sub-memory plane circuits.

For example, the first plane region PR1 may further include a third sub-memory plane circuit (not illustrated). The third sub-memory plane circuit may be connected to the first page buffer circuit PBC1 through third bit lines. The first page buffer circuit PBC1 may further include a third sense unit dedicated to the third sub-memory plane circuit. The third sense unit may include a third sense latch circuit and a third force latch circuit. The third sub-memory plane circuit may share the data latch circuit DLC and the cache latch circuit CLC with the first and second sub-memory plane circuits sMP11 and sMP12.

As described above, the components of the non-volatile memory device 120 are described with reference to FIGS. 4 and 5. The operation speed of the non-volatile memory device 120 may depend on the throughput of the memory plane circuit and the number of memory plane circuits.

In some implementations, one memory plane circuit dedicated to a page buffer circuit may be disposed for each plane region, but according to some implementations of the present disclosure, at least two sub-memory plane circuits sharing a page buffer circuit may be disposed for each plane region. Accordingly, the number of sub-memory plane circuits controlled in parallel in the non-volatile memory device 120 within the limited chip size may be increased, and the operation speed of the non-volatile memory device 120 may be increased.

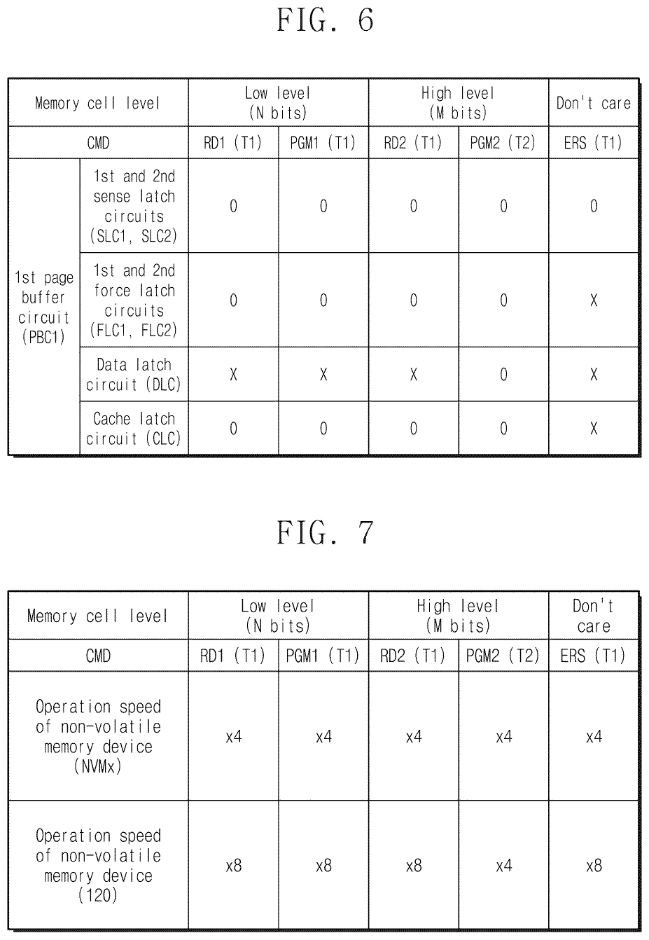

FIG. 6 is a table showing an example of a page buffer circuit and a command according to some implementations. A relationship between a memory operation which the command CMD indicates and components of the first page buffer circuit PBC1 will be described with reference to FIGS. 5 and 6.

The memory operation of the command CMD may be classified depending on a memory cell level. The memory cell level may indicate the number of bits which one memory cell transistor MC stores. The memory cell level is classified as a low level, a high level, and a “don't care”. The low level may correspond to “N bits” and may be also referred to as an “N-bit size”. “N” is an arbitrary natural number. The high level may correspond to “M bits” and may be also referred to as an “M-bit size”. “M” is a natural number greater than “N”. The “Don't care” may include the low level and the high level.

The command CMD may indicate the memory operation. Examples of the memory operation may include a first read operation RD1 for obtaining data of the N-bit size, a first program operation PGM1 for storing data of the N-bit size, a second read operation RD2 for obtaining data of the M-bit size, a second program operation PGM2 for storing data of the M-bit size(PGM2), and an erase operation ERS for deleting data.

In this case, the first read operation RD1, the first program operation PGM1, the second read operation RD2, and the erase operation ERS may correspond to the first type information T1. The second program operation PGM2 may correspond to the second type information T2.

The first page buffer circuit PBC1 may include the first sense latch SLC1, the second sense latch circuit SLC2, the first force latch circuit FLC1, the second force latch circuit FLC2, the data latch circuit DLC, and the cache latch circuit CLC. The first sense latch circuit SLC1 and the first force latch circuit FLC1 may be dedicated to the first sub-memory plane circuit sMP11. The second sense latch circuit SLC2 and the second force latch circuit FLC2 may be dedicated to the second sub-memory plane circuit sMP12. The data latch circuit DLC and the cache latch circuit CLC may be shared by the first and second sub-memory plane circuits sMP11 and sMP12.

Below, items of the table will be described. A mark of “O” may refer to the case where a corresponding latch circuit is used. A mark of “X” may refer to the case where a corresponding latch circuit is not used.

Referring to the column of the first read operation RD1, when the command CMD indicates the first read operation RD1, the first and second sense latch circuits SLC1 and SLC2, the first and second force latch circuits FLC1 and FLC2, and the cache latch circuit CLC may be used, and the data latch circuit DLC may not be used.

In some implementations, the first and second force latch circuits FLC1 and FLC2 may operate depending on a defense code of the first read operation RD1. The defense code may refer to information indicating an algorithm for preventing or recovering an error of data stored in the memory cell transistors MC.

Referring to the column of the first program operation PGM1, when the command CMD indicates the first program operation PGM1, the first and second sense latch circuits SLC1 and SLC2, the first and second force latch circuits FLC1 and FLC2, and the cache latch circuit CLC may be used, and the data latch circuit DLC may not be used.

In some implementations, whether to use the data latch circuit DLC may vary depending on whether a two-step verification technique is applied. The two-step verification technique may indicate a technique for performing a first verify operation based on a pre-verify voltage level and then performing a second verify voltage based on a voltage level higher than the pre-verify voltage level. When the two-step verification technique is applied to the first program operation PGM1 for storing data in the low level cell manner of the N-bit size, unlike the example illustrated in the table, the data latch circuit DLC may be used.

Referring to the column of the second read operation RD2, when the command CMD indicates the second read operation RD2, the first and second sense latch circuits SLC1 and SLC2, the first and second force latch circuits FLC1 and FLC2, and the cache latch circuit CLC may be used, and the data latch circuit DLC may not be used.

In some implementations, the first and second force latch circuits FLC1 and FLC2 may operate depending on a defense code of the second read operation RD2.

Referring to the column of the second program operation PGM2, when the command CMD indicates the second program operation PGM2, the first and second sense latch circuits SLC1 and SLC2, the first and second force latch circuits FLC1 and FLC2, the data latch circuit DLC, and the cache latch circuit CLC may be used.

In other words, all the components of the first page buffer circuit PBC1 may be used for the second program operation PGM2. Because the first and second sub-memory plane circuits sMP11 and sMP12 share the first page buffer circuit PBC1, the first and second sub-memory plane circuits sMP11 and sMP12 may be difficult to perform the second program operation PGM2 at the same time. The second program operation PGM2 may be performed in some of sub-memory plane circuits sharing a page buffer circuit.

Referring to the column of the erase operation ERS, when the command CMD indicates the erase operation ERS, the first and second sense latch circuits SLC1 and SLC2 may be used, the first and second force latch circuits FLC1 and FLC2, the data latch circuit DLC, and the cache latch circuit CLC may not be used.

FIG. 7 is a table showing an example of an operating speed of a non-volatile memory device according to some implementations. A memory operation which the command CMD indicates, an operation speed of the non-volatile memory device NVMx, and an operation speed of the non-volatile memory device 120 of the present disclosure will be described with reference to FIG. 7. The non-volatile memory device NVMx may correspond to the non-volatile memory device NVMx of FIG. 2. the non-volatile memory device 120 may correspond to the non-volatile memory device 120 of FIG. 4.

The memory operation of the command CMD may be classified depending on a memory cell level. The low level may correspond to N bits. “N” is an arbitrary natural number. The high level may correspond to M bits. “M” is a natural number greater than “N”. The “Don't care” may include the low level and the high level.

The command CMD may indicate the memory operation. Examples of the memory operation may include the first read operation RD1 for obtaining data of the N-bit size, the first program operation PGM1 for storing data of the N-bit size, the second read operation RD2 for obtaining data of the M-bit size, the second program operation PGM2 for storing data of the M-bit size(PGM2), and the erase operation ERS for deleting data.

In this case, the first read operation RD1, the first program operation PGM1, the second read operation RD2, and the erase operation ERS may correspond to the first type information T1. The second program operation PGM2 may correspond to the second type information T2.

Referring to the columns of the first read operation RD1, the first program operation PGM1, the second read operation RD2, and the erase operation ERS corresponding to the first type information T1, when the command CMD indicates the first type information T1, the conventional non-volatile memory device NVMx may support a 4x speed operation. The non-volatile memory device 120 may support an 8x speed operation.

For example, the non-volatile memory device NVMx of FIG. 2 may include four memory plane circuits MPx1, MPx2, MPx3, and MPx4 and four page buffer circuits PBCx1, PBCx2, PBCx3, and PBCx4. The four page buffer circuits PBCx1, PBCx2, PBCx3, and PBCx4 may be dedicated to the four memory plane circuits MPx1, MPx2, MPx3, and MPx4. The non-volatile memory device NVMx may perform the memory operation corresponding to the first type information T1 in parallel in the four memory plane circuits MPx1, MPx2, MPx3, and MPx4. Accordingly, the non-volatile memory device NVMx may support the 4× speed operation.

As another, the non-volatile memory device 120 of FIG. 4 may include eight sub-memory plane circuits sMP11, sMP12, sMP21, sMP22, sMP31, sMP32, sMP41, and sMP42 and four page buffer circuits PBC1, PBC2, PBC3, and PBC4. The four page buffer circuits PBC1, PBC2, PBC3, and PBC4 may be shared by to the eight sub-memory plane circuits sMP11, sMP12, sMP21, sMP22, sMP31, sMP32, sMP41, and sMP42. The non-volatile memory device non-volatile memory device 120 may perform the memory operation corresponding to the first type information T1 in parallel in the eight sub-memory plane circuits sMP11, sMP12, sMP21, sMP22, sMP31, sMP32, sMP41, and sMP42. Accordingly, the non-volatile memory device 120 may support the 8× speed operation.

Referring to the column of the second program operation PGM2 corresponding to the second type information T2, when the command CMD indicates the second type information T2, the conventional non-volatile memory device NVMx may support the 4× speed operation. The non-volatile memory device 120 may support the 4× speed operation.

For example, the non-volatile memory device NVMx of FIG. 2 may include four memory plane circuits MPx1, MPx2, MPx3, and MPx4 and four page buffer circuits PBCx1, PBCx2, PBCx3, and PBCx4. The conventional non-volatile memory device NVMx may perform the memory operation corresponding to the second type information T2 in parallel in the four memory plane circuits MPx1, MPx2, MPx3, and MPx4. Accordingly, the non-volatile memory device NVMx may support the 4× speed operation. In other words, the non-volatile memory device NVMx may support the 4× speed operation regardless of type information.

As another, the non-volatile memory device 120 of FIG. 4 may include eight sub-memory plane circuits sMP11, sMP12, sMP21, sMP22, sMP31, sMP32, sMP41, and sMP42 and four page buffer circuits PBC1, PBC2, PBC3, and PBC4. Each of the page buffer circuits PBC1, PBC2, PBC3, and PBC4 may include one data latch circuit. The data latch circuit may be shared by two sub-memory plane circuits. Because the data latch circuit is used in the second program operation PGM2, the non-volatile memory device 120 may enable only one of two sub-memory plane circuits sharing the data latch circuit. The non-volatile memory device 120 may perform the memory operation corresponding to the second type information T2 in parallel in four sub-memory plane circuits among the eight sub-memory plane circuits sMP11, sMP12, sMP21, sMP22, sMP31, sMP32, sMP41, and sMP42. Accordingly, the non-volatile memory device 120 may support the 4× speed operation.

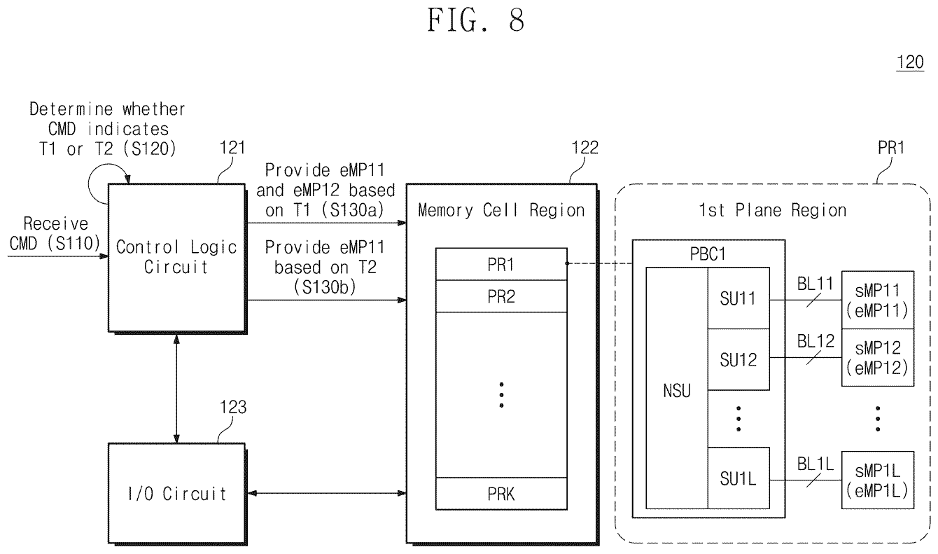

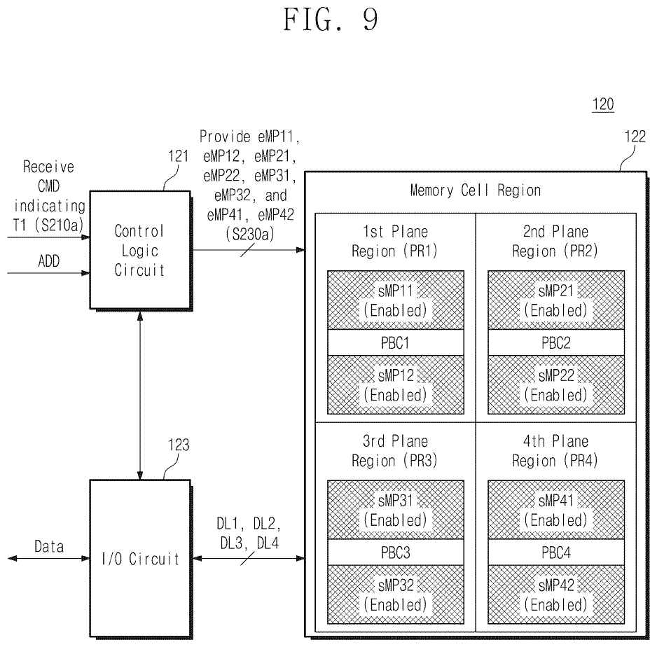

FIG. 8 is a diagram showing an example of a method of operating a non-volatile memory device according to some implementations. In FIG. 8, the non-volatile memory device 120 may include the control logic circuit 121, the memory cell region 122, and the I/O circuit 123. The memory cell region 122 may include a plurality of plane regions PR1 to PRK. “K” is an arbitrary natural number. The plane region may refer to a physical space in which a page buffer circuit and at least one sub-memory plane circuit sharing the page buffer circuit are disposed.

The first plane region PR1 may include first to L-th sub-memory plane circuits sMP11 to sMP1L and the first page buffer circuit PBC1. “L” is an arbitrary natural number. The first to L-th sub-memory plane circuits sMP11 to sMP1L may share the first page buffer circuit PBC1. The first page buffer circuit PBC1 may include first to L-th sense units SU11 to SU1L and the non-sense unit NSU. The first to L-th sense units SU11 to SU1L may be respectively dedicated to the first to L-th sub-memory plane circuits sMP11 to sMP1L. The non-sense unit NSU may be shared by the first to L-th sub-memory plane circuits sMP11 to sMP1L.

The first sub-memory plane circuit sMP11 may be connected to the first sense unit SU11 of the first page buffer circuit PBC1 through the first bit lines BL11. The first sub-memory plane circuit sMP11 may be enabled based on the enable signal eMP11.

The second sub-memory plane circuit sMP12 may be connected to the second sense unit SU12 of the first page buffer circuit PBC1 through the second bit lines BL12. The second bit lines BL12 may be different from the first bit lines BL11. The second sub-memory plane circuit sMP12 may be enabled based on the enable signal eMP12.

The L-th sub-memory plane circuit sMP1L may be connected to the L-th sense unit SU1L of the first page buffer circuit PBC1 through L-th bit lines BL1L. The L-th bit lines BL1L may be different from the first bit lines BL11 and the second bit lines BL12. The L-th sub-memory plane circuit sMP1L may be enabled based on an enable signal eMP1L.

To avoid the duplication of description, the first plane region PR1 among the first to K-th plane regions PR1 to PRK of the memory cell region 122 is described, but the present disclosure is not limited thereto. The above description will be similarly applied to the second to K-th plane regions PR2 to PRK.

Below, an example of a method of operating the non-volatile memory device 120 will be described.

In operation S110, the control logic circuit 121 may receive the command CMD from the storage controller 110 of FIG. 1. The command CMD may indicate the first type information T1 or the second type information T2. The first type information T1 may correspond to the first read operation, the first program operation, the second read operation, and the erase operation. The second type information T2 may correspond to the second program operation.

In operation S120, the control logic circuit 121 may determine whether the command CMD indicates the first type information T1 or the second type information T2. The control logic circuit 121 may perform operation S130a in response to determining that the command CMD indicates the first type information T1. The control logic circuit 121 may perform operation S130b in response to determining that the command CMD indicates the second type information T2.

In operation S130a, in response to determining that the command CMD indicates the first type information T1, the control logic circuit 121 may provide the enable signal eMP11 and the enable signal eMP12 to the first sub-memory plane circuit sMP11 and the second sub-memory plane circuit sMP12, respectively. In other words, the control logic circuit 121 may enable all of the first and second sub-memory plane circuits sMP11 and sMP12, based on the command CMD indicating the first type information T1.

In operation S130b, in response to determining that the command CMD indicates the second type information T2, the control logic circuit 121 may provide the enable signal eMP11 to the first sub-memory plane circuit sMP11. In other words, the control logic circuit 121 may enable the first sub-memory plane circuit sMP11 among the first and second sub-memory plane circuits sMP11 and sMP12, based on the command CMD indicating the second type information T2. That is, the control logic circuit 121 may disable the second sub-memory plane circuits sMP12 in response to determining that the command CMD indicates the second type information T2.

In some implementations, the control logic circuit 121 may further manage the second plane region PR2. For example, the second plane region PR2 may further include a second page buffer circuit, a third sub-memory plane circuit, and a fourth sub-memory plane circuit. The third sub-memory plane circuit may be directly connected to the second page buffer circuit PBC2 through third bit lines different from the first bit lines BL11 and the second bit lines BL12. The fourth sub-memory plane circuit may be directly connected to the second page buffer circuit PBC2 through fourth bit lines different from the first bit lines BL11, the second bit lines BL12, and the third bit lines. The control logic circuit 121 may enable the third and fourth sub-memory plane circuits in response to determining that the command CMD indicates the first type information T1. The control logic circuit 121 may disable the third sub-memory plane circuit in response to determining that the command CMD indicates the second type information T2.

In some implementations, the first plane region PR1 may include three or more sub-memory plane circuits. For example, “L” may be greater than or equal to 3. The first plane region PR1 may further include the third sub-memory plane circuit sMP13. The third sub-memory plane circuit sMP13 may be directly connected to the first page buffer circuit PBC1 through third bit lines BL13 different from the first bit line BL11 and the second bit lines BL12. The control logic circuit 121 may enable the third sub-memory plane circuits sMP13 in response to determining that the command CMD indicates the first type information T1.

In some implementations, the control logic circuit 121 may enable two or more sub-memory plane circuits among three or more sub-memory plane circuits, based on the command CMD indicating the second type information T2. For example, “L” may be greater than or equal to 3. The first plane region PR1 may further include the third sub-memory plane circuit sMP13. The control logic circuit 121 may enable the third sub-memory plane circuits sMP13 in response to determining that the command CMD indicates the second type information T2. That is, the control logic circuit 121 may enable the first and third sub-memory circuits sMP11 and sMP13 among the first to third sub-memory plane circuits sMP11, sMP12, and sMP13, based on the command CMD indicating the second type information T2.

In some implementations, the control logic circuit 121 may disable two or more sub-memory plane circuits among three or more sub-memory plane circuits, based on the command CMD indicating the second type information T2. For example, “L” may be greater than or equal to 3. The first plane region PR1 may further include the third sub-memory plane circuit sMP13. The control logic circuit 121 may disable the third sub-memory plane circuits sMP13 in response to determining that the command CMD indicates the second type information T2. That is, the control logic circuit 121 may disable the second and third sub-memory circuits sMP12 and sMP13 among the first to third sub-memory plane circuits sMP11, sMP12, and sMP13, based on the command CMD indicating the second type information T2.

In some implementations, the first page buffer circuit PBC1 may be shared by three or more sub-memory plane circuits. For example, “L” may be greater than or equal to 3. The first plane region PR1 may further include the third sub-memory plane circuit sMP13. The first page buffer circuit PBC1 may further include the third sense unit SU13 dedicated to the third sub-memory plane circuit sMP13.

In detail, the first sense unit SU11 may include a first sense latch circuit and a first force latch circuit. The first sense latch circuit may be dedicated to the first sub-memory plane circuit sMP11. The first force latch circuit may be dedicated to the first sub-memory plane circuit sMP11. The second sense unit SU12 may include a second sense latch circuit and a second force latch circuit. The second sense latch circuit may be dedicated to the second sub-memory plane circuit sMP12. The second force latch circuit may be dedicated to the second sub-memory plane circuit sMP12. The third sense unit SU13 may include a third sense latch circuit and a third force latch circuit. The third sense latch circuit may be dedicated to the third sub-memory plane circuit sMP13. The third force latch circuit may be dedicated to the third sub-memory plane circuit sMP13. The non-sense unit NSU may include a data latch circuit and a cache latch circuit. The data latch circuit may be shared by the first to third sub-memory plane circuits sMP11, sMP12, and sMP13. The cache latch circuit may be shared by the first to third sub-memory plane circuits sMP11, sMP12, and sMP13.

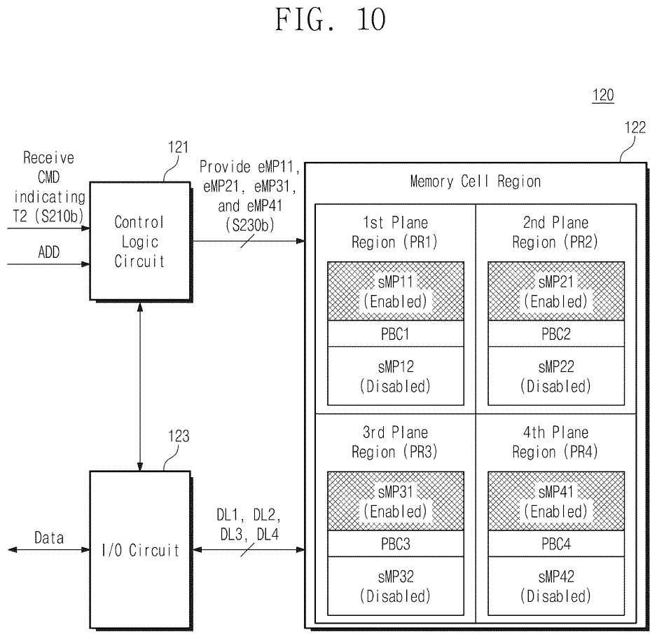

FIG. 9 is a diagram showing an example of a first-type multi-plane operation according to some implementations. In FIG. 9, the non-volatile memory device 120 may include the control logic circuit 121, the memory cell region 122, and the I/O circuit 123. The memory cell region 122 may include the first to fourth plane regions PR1 to PR4.

The control logic circuit 121 may receive the command CMD and the address ADD from the storage controller 110 of FIG. 1. The control logic circuit 121 may control the memory cell region 122 and the I/O circuit 123. The I/O circuit 123 may be connected to the first to fourth page buffer circuits PB1 to PBC4 through the first to fourth data lines DL1 to DL4. Under control of the control logic circuit 121, the I/O circuit 123 may communicate data with the storage controller 110 of FIG. 1.

The first plane region PR1 may include the first page buffer circuit PBC1, the first sub-memory plane circuit sMP11, and the second sub-memory plane circuit sMP12. The first and second sub-memory plane circuits sMP11 and sMP12 may share the first page buffer circuit PBC1.

The second plane region RP2 may include the second page buffer circuit PBC2, the first sub-memory plane circuit sMP21, and the second sub-memory plane circuit sMP22. The first and second sub-memory plane circuits sMP21 and sMP22 may share the second page buffer circuit PBC2.

The third plane region PR3 may include the third page buffer circuit PBC3, the first sub-memory plane circuit sMP31, and the second sub-memory plane circuit sMP32. The first and second sub-memory plane circuits sMP31 and sMP32 may share the third page buffer circuit PBC3.

The fourth plane region PR4 may include the fourth page buffer circuit PBC4, the first sub-memory plane circuit sMP41, and the second sub-memory plane circuit sMP42. The first and second sub-memory plane circuits sMP41 and sMP42 may share the fourth page buffer circuit PBC4.

Below, an example of a method of operating the non-volatile memory device 120 will be described.

In operation S210a, the control logic circuit 121 may receive the command CMD from the storage controller 110 of FIG. 1. The command CMD may indicate the first type information T1.

In operation S230a, the control logic circuit 121 may perform the first-type multi-plane operation, based on the command CMD indicating the first type information T1. The first-type multi-plane operation may indicate the enable of all sub-memory plane circuits. For example, the control logic circuit 121 may provide enable signals eMP11, eMP12, eMP21, eMP22, eMP31, eMP32, eMP41, and eMP42 to the sub-memory plane circuits sMP11, sMP12, sMP21, sMP22, sMP31, sMP32, sMP41, and sMP42 in response to determining that the command CMD indicates the first type information T1.

The sub-memory plane circuits sMP11, sMP12, sMP21, sMP22, sMP31, sMP32, sMP41, and sMP42 may be enabled respectively based on the enable signals eMP11, eMP12, eMP21, eMP22, eMP31, eMP32, eMP41, and eMP42. An enabled sub-memory plane circuit is shaded. That is, all the sub-memory plane circuits sMP11, sMP12, sMP21, sMP22, sMP31, sMP32, sMP41, and sMP42 may be enabled depending on the first-type multi-plane operation.

FIG. 10 is a diagram showing an example of a second-type multi-plane operation according to some implementations. In FIG. 10, the non-volatile memory device 120 may include the control logic circuit 121, the memory cell region 122, and the I/O circuit 123. The control logic circuit 121, the memory cell region 122, and the I/O circuit 123 are similar to the control logic circuit 121, the memory cell region 122, and the I/O circuit 123 of FIG. 9, and thus, additional description will be omitted to avoid redundancy.

Below, an example of a method of operating the non-volatile memory device 120 will be described.

In operation S210b, the control logic circuit 121 may receive the command CMD from the storage controller 110 of FIG. 1. The command CMD may indicate the second type information T2.

In operation S230b, the control logic circuit 121 may perform the second-type multi-plane operation, based on the command CMD indicating the second type information T2. The second-type multi-plane operation may indicate the enable of some of all sub-memory plane circuits. For example, the control logic circuit 121 may provide the enable signals eMP11, eMP21, eMP31, and eMP41 to the sub-memory plane circuits sMP11, sMP21, sMP31, and sMP41 in response to determining that the command CMD indicates the second type information T2.

The sub-memory plane circuits sMP11, sMP21, sMP31, and sMP41 may be enabled respectively based on the enable signals eMP11, eMP21, eMP31, and eMP41. An enabled sub-memory plane circuit is shaded. That is, depending on the second-type multi-plane operation, the sub-memory plane circuits sMP11, sMP21, sMP31, and sMP41 among the sub-memory plane circuits sMP11, sMP12, sMP21, sMP22, sMP31, sMP32, sMP41, and sMP42 may be enabled, and the remaining sub-memory plane circuits sMP12, sMP22, sMP32, and sMP42 may not be enabled.

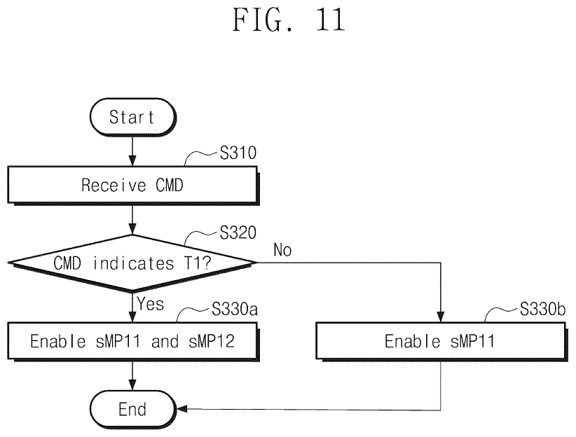

FIG. 11 is a flowchart showing an example of a method of operating a non-volatile memory device according to some implementations. In FIG. 11, a non-volatile memory device may communicate with a storage controller. The non-volatile memory device may include a page buffer circuit, the first sub-memory plane circuit sMP11, and the second sub-memory plane circuit sMP12. The third sub-memory plane circuit sMP11 may be directly connected to the page buffer circuit through first bit lines. The second sub-memory plane circuit sMP12 may be directly connected to the page buffer circuit through second bit lines.

In operation S310, the non-volatile memory device may receive the command CMD from the storage controller.

In operation S320, the non-volatile memory device may determine whether the command CMD indicates the first type information T1. The non-volatile memory device may perform operation S330a in response to determining that the command CMD indicates the first type information T1.

In operation S330a, the non-volatile memory device may enable the first and second sub-memory plane circuits sMP11 and sMP12.

Returning to operation S320, the non-volatile memory device may perform operation S330b in response to determining that the command CMD does not indicate the first type information T1. For example, the command CMD may indicate the second type information T2 different from the first type information T1.

In operation S330b, the non-volatile memory device may enable the first sub-memory plane circuit sMP11. In this case, the non-volatile memory device may disable the second sub-memory plane circuit sMP12.

In some implementations, the non-volatile memory device may include any other page buffer circuit, a third sub-memory plane circuit, and a fourth sub-memory plane circuit. The third sub-memory plane circuit may be directly connected to the other page buffer circuit through third bit lines. The fourth sub-memory plane circuit may be directly connected to the other page buffer circuit through fourth bit lines. The non-volatile memory device may enable the third and fourth sub-memory plane circuits in response to determining that the command CMD indicates the first type information T1. In response to determining that the command CMD does not indicate the first type information T1, the non-volatile memory device may enable the third sub-memory plane circuit and may disable the fourth sub-memory plane circuit.

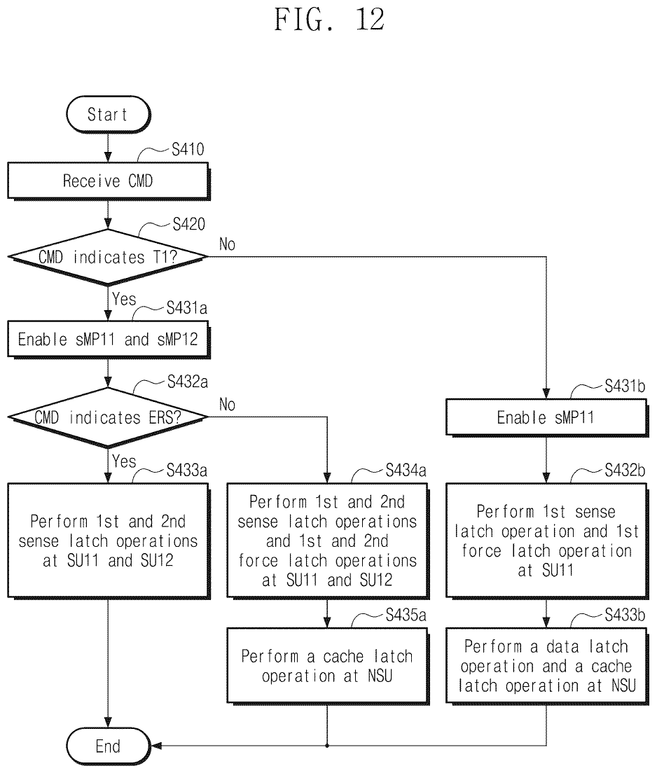

FIG. 12 is a flowchart showing an example of a method of operating a non-volatile memory device according to some implementations. In FIG. 12, a non-volatile memory device may communicate with a storage controller. The non-volatile memory device may include a page buffer circuit, the first sub-memory plane circuit sMP11, and the second sub-memory plane circuit sMP12. The first and second sub-memory plane circuits sMP11 and sMP12 may share the page buffer circuit.

The page buffer circuit may include the first sense unit SU11, the second sense unit SU12, and the non-sense unit NSU. The first sense unit SU11 may be dedicated to the first sub-memory plane circuit sMP11. The second sense unit SU12 may be dedicated to the second sub-memory plane circuit sMP12. The non-sense unit NSU may be shared by the first and second sub-memory plane circuits sMP11 and sMP12.

In operation S410, the non-volatile memory device may receive the command CMD from the storage controller.

In operation S420, the non-volatile memory device may determine whether the command CMD indicates the first type information T1. The non-volatile memory device may perform operation S431a in response to determining that the command CMD indicates the first type information T1.

In operation S431a, the non-volatile memory device may enable the first and second sub-memory plane circuits sMP11 and sMP12.

In operation S432a, the non-volatile memory device may determine whether the command CMD indicates the erase operation ERS. The non-volatile memory device may perform operation S433a in response to determining that the command CMD indicates the erase operation ERS.

In operation S433a, the non-volatile memory device may perform first and second sense latch operations in the first and second sense units SU11 and SU12. The first sense latch operation may indicate an operation of sensing voltage levels corresponding to memory cell transistors of the first sub-memory plane circuit sMP11. The second sense latch operation may indicate an operation of sensing voltage levels corresponding to memory cell transistors of the second sub-memory plane circuit sMP12.

Returning to operation S432a, the non-volatile memory device may perform operation S434a in response to determining that the command CMD does not indicate the erase operation ERS.

In operation S434a, the non-volatile memory device may perform the first and second sense latch operations and first and second force latch operations in the first and second sense units SU11 and SU12. The first force latch operation may indicate an operation of adjusting a distribution of the voltage levels corresponding to the memory cell transistors of the first sub-memory plane circuit sMP11. The second force latch operation may indicate an operation of adjusting a distribution of the voltage levels corresponding to the memory cell transistors of the second sub-memory plane circuit sMP12.

In operation S435a, the non-volatile memory device may perform the cache latch operation in the non-sense unit NSU. The cache latch operation indicate may refer to an operation of temporarily storing the read data or the data to be programmed. The cache latch operation may correspond to the first and/or second sub-memory plane circuit sMP11 and/or sMP12.

Returning to operation S420, the non-volatile memory device may perform operation S431b in response to determining that the command CMD does not indicate the first type information T1.

In operation S431b, the non-volatile memory device may enable the first sub-memory plane circuit sMP11. The non-volatile memory device may disable the second sub-memory plane circuit sMP12.

In operation S432b, the non-volatile memory device may perform the first sense latch operation and the first force latch operation in the first sense unit SU11.

In operation S433b, the non-volatile memory device may perform the data latch operation and the cache latch operation in the non-sense unit NSU. The data latch operation may refer to an operation of temporarily storing the data to be programmed. The data latch operation and the cache latch operation may correspond to the first sub-memory plane circuit sMP11 enabled from among the first and second sub-memory plane circuits sMP11 and sMP12.

According to the present disclosure, a non-volatile memory device enabling a memory plane circuit, a storage device including the same, and a method of operating the same are provided.

Also, according to the present disclosure, because sub-memory plane circuits share a page buffer circuit, the number of memory plane circuits controlled in parallel in the non-volatile memory device within the limited chip size and an operation speed of the non-volatile memory device may be increased.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A non-volatile memory device comprising:
a first page buffer circuit;
a first sub-memory plane circuit directly connected to the first page buffer circuit through a plurality of first bit lines;
a second sub-memory plane circuit directly connected to the first page buffer circuit through a plurality of second bit lines that are different from the plurality of first bit lines; and
a control logic circuit,
wherein the control logic circuit is configured to:
receive a command from a storage controller;
determine that the command indicates first type information or second type information;
enable the first sub-memory plane circuit and the second sub-memory plane circuit based on determining that the command indicates the first type information; and
enable the first sub-memory plane circuit based on determining that the command indicates the second type information.

2. The non-volatile memory device of claim 1, wherein the control logic circuit is configured to:
disable the second sub-memory plane circuit based on determining that the command indicates the second type information.

3. The non-volatile memory device of claim 1,
wherein the command indicates:
a first read operation for obtaining first data of an N-bit size;
a first program operation for storing second data of the N-bit size;
a second read operation for obtaining third data of an M-bit size;
a second program operation for storing fourth data of the M-bit size; or
an erase operation for deleting fifth data,
wherein “N” is a natural number, and
wherein “M” is a natural number greater than “N”.

4. The non-volatile memory device of claim 3,
wherein the first type information corresponds to the first read operation, the first program operation, the second read operation, and the erase operation, and
wherein the second type information corresponds to the second program operation.

5. The non-volatile memory device of claim 3, wherein the first page buffer circuit includes:
a first sense latch circuit configured to sense first voltage levels, which correspond to the first sub-memory plane circuit, based on the first read operation, the first program operation, the second read operation, the second program operation, or the erase operation, and
a second sense latch circuit configured to sense second voltage levels, which correspond to the second sub-memory plane circuit, based on the first read operation, the first program operation, the second read operation, the second program operation, or the erase operation.

6. The non-volatile memory device of claim 3, wherein the first page buffer circuit includes:
a first force latch circuit configured to adjust a first distribution of first voltage levels, which correspond to the first sub-memory plane circuit, based on the first read operation, the first program operation, the second read operation, or the second program operation; and
a second force latch circuit configured to adjust a second distribution of second voltage levels, which correspond to the second sub-memory plane circuit, based on the first read operation, the first program operation, the second read operation, or the second program operation.

7. The non-volatile memory device of claim 3, wherein the first page buffer circuit includes:
a data latch circuit configured to perform a data latch operation of the fourth data corresponding to the first sub-memory plane circuit or to the second sub-memory plane circuit, based on the second program operation.

8. The non-volatile memory device of claim 7,
wherein the fourth data include first to M-th bits,
wherein the data latch operation includes first to M-th bit latch operations respectively corresponding to the first to M-th bits, and
wherein the data latch circuit includes first to M-th bit latch circuits configured to perform the first to M-th bit latch operations, respectively, based on the second program operation.

9. The non-volatile memory device of claim 3, wherein the first page buffer circuit includes:
a cache latch circuit configured to perform a cache latch operation corresponding to the first sub-memory plane circuit or to the second sub-memory plane circuit, based on the first read operation, the first program operation, the second read operation, or the second program operation.

10. The non-volatile memory device of claim 1, comprising:
a second page buffer circuit;
a third sub-memory plane circuit directly connected to the second page buffer circuit through a plurality of third bit lines that are different from the plurality of first bit lines and from the plurality of second bit lines; and
a fourth sub-memory plane circuit directly connected to the second page buffer circuit through a plurality of fourth bit lines that are different from the plurality of first bit lines, from the plurality of second bit lines, and from the plurality of third bit lines, and
wherein the control logic circuit is configured to:
enable the third sub-memory plane circuit and the fourth sub-memory plane circuit based on determining that the command indicates the first type information; and
enable the third sub-memory plane circuit based on determining that the command indicates the second type information.

11. The non-volatile memory device of claim 1, comprising:
a third sub-memory plane circuit connected to the first page buffer circuit through a plurality of third bit lines different from the plurality of first bit lines and the plurality of second bit lines,
wherein the control logic circuit is configured to enable the third sub-memory plane circuit based on determining that the command indicates the first type information.

12. The non-volatile memory device of claim 11, wherein the control logic circuit is configured to:
enable the third sub-memory plane circuit based on determining that the command indicates the second type information.

13. The non-volatile memory device of claim 11, wherein the control logic circuit is configured to:
disable the second and third sub-memory plane circuits based on determining that the command indicates the second type information.

14. The non-volatile memory device of claim 11, wherein the first page buffer circuit includes:
a first sense latch circuit dedicated to the first sub-memory plane circuit;
a first force latch circuit dedicated to the first sub-memory plane circuit;
a second sense latch circuit dedicated to the second sub-memory plane circuit;
a second force latch circuit dedicated to the second sub-memory plane circuit;
a third sense latch circuit dedicated to the third sub-memory plane circuit;
a third force latch circuit dedicated to the third sub-memory plane circuit;
a data latch circuit shared by the first sub-memory plane circuit, the second sub-memory plane circuit, and the third sub-memory plane circuit; and
a cache latch circuit shared by the first sub-memory plane circuit, the second sub-memory plane circuit, and the third sub-memory plane circuit.

15. A storage device comprising:
a storage controller configured to generate a command; and
a non-volatile memory device including a first page buffer circuit, a first sub-memory plane circuit, and a second sub-memory plane circuit,
wherein the first page buffer circuit is directly connected to the first sub-memory plane circuit and the second sub-memory plane circuit, and
wherein the non-volatile memory device is configured to:
receive the command from the storage controller;
determine that the command indicates first type information or second type information;
enable the first sub-memory plane circuit and the second sub-memory plane circuit based on determining that the command indicates the first type information; and
enable the first sub-memory plane circuit based on determining that the command indicates the second type information.

16. The storage device of claim 15, wherein the non-volatile memory device includes:
a second page buffer circuit, a third sub-memory plane circuit, and a fourth sub-memory plane circuit,
wherein the second page buffer circuit is directly connected to the third sub-memory plane circuit and the fourth sub-memory plane circuit, and
wherein the non-volatile memory device is configured to:
enable the third sub-memory plane circuit and the fourth sub-memory plane circuit based on determining that the command indicates the first type information; and
enable the third sub-memory plane circuit based on determining that the command indicates the second type information.

17. The storage device of claim 15, wherein the first page buffer circuit includes:
a first sense latch circuit dedicated to the first sub-memory plane circuit;
a first force latch circuit dedicated to the first sub-memory plane circuit;
a second sense latch circuit dedicated to the second sub-memory plane circuit;
a second force latch circuit dedicated to the second sub-memory plane circuit;
a data latch circuit shared by the first sub-memory plane circuit and the second sub-memory plane circuit; and
a cache latch circuit shared by the first sub-memory plane circuit and the second sub-memory plane circuit.

18. A method of operating a non-volatile memory device configured to communication with a storage controller, the method comprising:
receiving a command from the storage controller;
determining that the command indicates first type information or second type information;
enabling a first sub-memory plane circuit and a second sub-memory plane circuit of the non-volatile memory device based on determining that the command indicates the first type information, wherein the first sub-memory plane circuit and the second sub-memory plane circuit are directly connected to a first page buffer circuit of the non-volatile memory device; or
enabling the first sub-memory plane circuit based on determining that the command indicates the second type information.

19. The method of claim 18,
wherein the command indicates:
a first read operation for obtaining first data of an N-bit size;
a first program operation for storing second data of the N-bit size;
a second read operation for obtaining third data of an M-bit size;
a second program operation for storing fourth data of the M-bit size; or
an erase operation for deleting fifth data,
wherein the first type information corresponds to the first read operation, the first program operation, the second read operation, and the erase operation, and
wherein the second type information corresponds to the second program operation,
wherein “N” is a natural number, and
wherein “M” is a natural number greater than “N”.

20. The method of claim 18, comprising:
enabling a third sub-memory plane circuit and a fourth sub-memory plane circuit of the non-volatile memory device based on determining that the command indicates the first type information, wherein the third sub-memory plane circuit and the fourth sub-memory plane circuit are directly connected to a second page buffer circuit of the non-volatile memory device; or
enabling the third sub-memory plane circuit based on determining that the command indicates the second type information.
